(19) United States
(12) Patent Application Publication
(10) Pub. No.: US 2013/0160818 A1
(43) Pub. Date: Jun. 27, 2013

(54) SOLAR CELL SYSTEM

(71) Applicants: QUN-QING LI, Beijing (CN); YUAN-HAO JIN, Beijing (CN); SHOU-SHAN FAN, Beijing (CN)

(72) Inventors: QUN-QING LI, Beijing (CN); YUAN-HAO JIN, Beijing (CN); SHOU-SHAN FAN, Beijing (CN)

(73) Assignees: HON HAI PRECISION INDUSTRY CO., LTD., Tu-Cheng (TW); TSINGHUA UNIVERSITY, Beijing (CN)

(21) Appl. No.: 13/596,159

(22) Filed: Aug. 28, 2012

(30) Foreign Application Priority Data
Dec. 22, 2011 (CN) 201110436116.6

(51) Int. Cl. H01L 31/052

(52) U.S. Cl. 136/246

(57) ABSTRACT

A solar cell system includes a substrate, a number of solar cells and a number of reflectors. The substrate defines a number of grooves spaced from each other. Each solar cell is located in each groove. Each solar cell includes a first electrode layer, a P-type silicon layer, an N-type silicon layer, and a second electrode layer arranged in series side by side along a first direction and in contact with each other, thereby cooperatively forming an integrated structure. A P-N junction is formed between the P-type silicon layer and the N-type silicon layer. The integrated structure has a photoreceptive surface to expose the P-N junction and receive an incident light directly. Each reflector is located between each solar cell and each groove.

### CROSS-REFERENCE TO RELATED APPLICATIONS

This application claims all benefits accruing under 35 U.S.C. §119 from China Patent Application No. 201110436116.6, filed on Dec. 22, 2011, in the China Intellectual Property Office, the contents of which are hereby incorporated by reference. This application is related to applications entitled, “SOLAR CELL SYSTEM”, filed ______ (Atty. Docket No. US41705); “SOLAR CELL SYSTEM SUBSTRATE”, filed ______ (Atty. Docket No. US44060).

### BACKGROUND

1. Technical Field

The present disclosure relates to a solar cell system substrate and a solar cell system using the same.

2. Description of Related Art

An operating principle of a solar cell is based on the photoelectric effect of a semiconducting material. The solar cells can be roughly classified into silicon-based solar cells, gallium arsenide solar cells, and organic thin film solar cells.

A silicon-based solar cell usually includes a rear electrode, a P-type silicon layer, an N-type silicon layer, and a front electrode. The P-type silicon layer can be made of polycrystalline silicon or monocrystalline silicon and has a first surface and a flat second surface opposite to the first surface. The rear electrode is located on and in ohmic contact with the first surface of the P-type silicon layer. The N-type silicon layer is on the second surface of the P-type silicon layer and serves as a photoelectric conversion element. The N-type silicon layer has a flat surface. The front electrode is located on the flat surface of the N-type silicon layer. The P-type silicon layer and the N-type silicon layer cooperatively form a P-N junction near an interface of the P-type silicon layer and the N-type silicon layer. In use, light directly irradiates the front electrode, and reaches the P-N junction through the front electrode and the N-type silicon layer. Consequently, a plurality of electron-hole pairs (carriers) can be generated in the P-N junction due to photon excitation. Electrons and holes in the electron-hole pairs can be separated from each other and separately move toward the rear electrode and the front electrode under an electrostatic potential. If a load is connected between the front electrode and the rear electrode, a current can flow through the load.

However, a light absorbing efficiency of the P-N junction of the above solar cell is low, because photons in the incident light are partially absorbed by the front electrode and the N-type silicon layer. Thus, the number of carriers generated by exciting of photons in the P-N junction may be low, and a photoelectric conversion efficiency of the solar cell is relatively low.

What is needed, therefore, is to provide a solar cell having high photoelectric conversion efficiency.

### BRIEF DESCRIPTION OF THE DRAWING

Many aspects of the present disclosure can be better understood with reference to the following drawings. The components in the drawings are not necessarily to scale, the emphasis instead being placed upon clearly illustrating the principles of the present embodiments.

FIG. 1 is a schematic top view of a first embodiment of a solar cell system including a plurality of solar cells electrically connected in series and a substrate defining a plurality of grooves.

FIG. 2 is a schematic, cross-sectional view of the solar cell system, along a line II-II of FIG. 1.

FIG. 3 is an enlarged view of a single groove and a single solar cell of FIG. 1.

FIG. 4 is a schematic view of a single solar cell of FIG. 1.

FIG. 5 is a schematic top view of a first embodiment of a solar cell system including a plurality of solar cells electrically connected in parallel.

FIG. 6 is a schematic view of a second embodiment of a solar cell system.

FIG. 7 is a schematic view of a third embodiment of a solar cell system.

FIG. 8 is a schematic view of a fourth embodiment of a solar cell system.

FIG. 9 is a schematic view of a fifth embodiment of a solar cell system.

FIG. 10 is a schematic view of a sixth embodiment of a solar cell system.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean at least one.

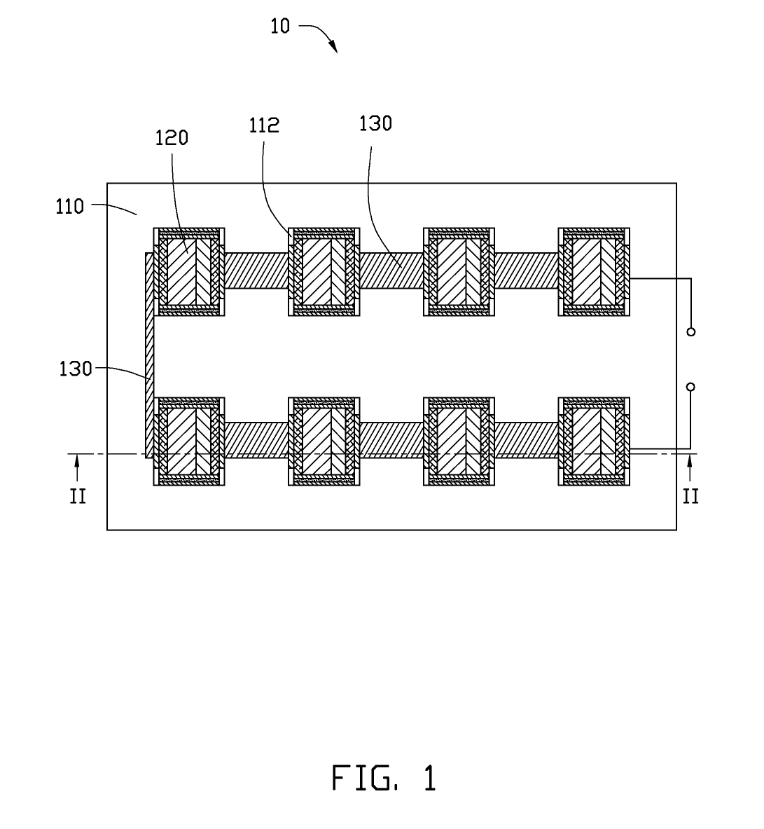

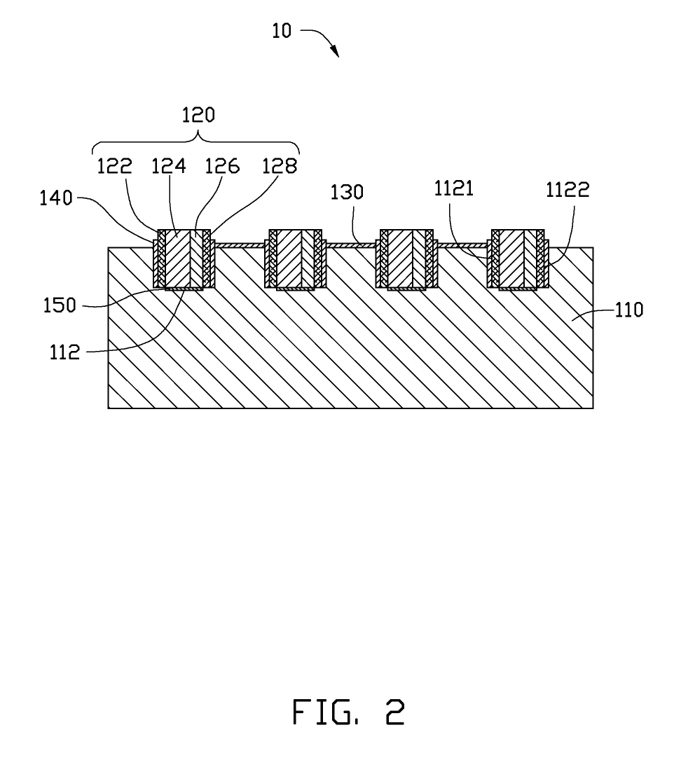

Referring to FIGS. 1-2, a first embodiment of a solar cell system 10 includes a substrate 110 and a plurality of solar cells 120. The substrate 110 includes a body defining a plurality of grooves 112 spaced from each other. Each of the plurality of solar cells 120 is located in each of the plurality of grooves 112.

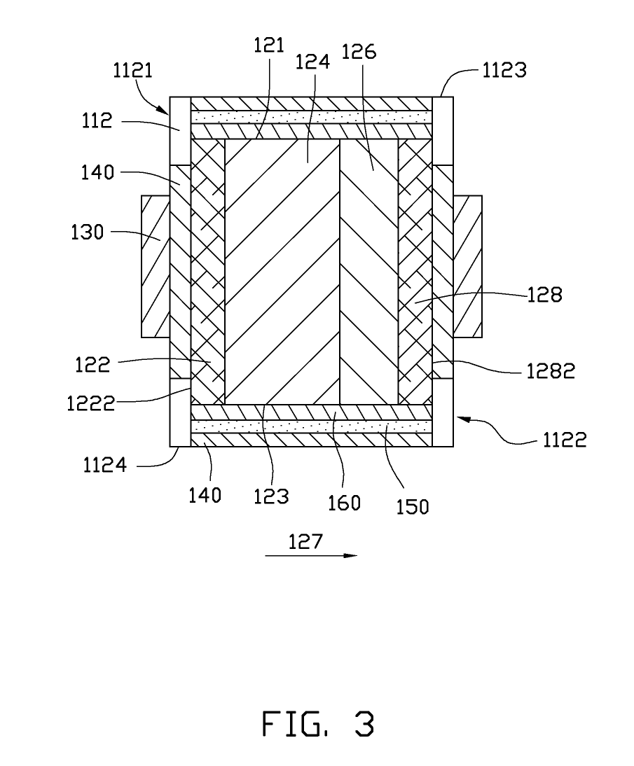

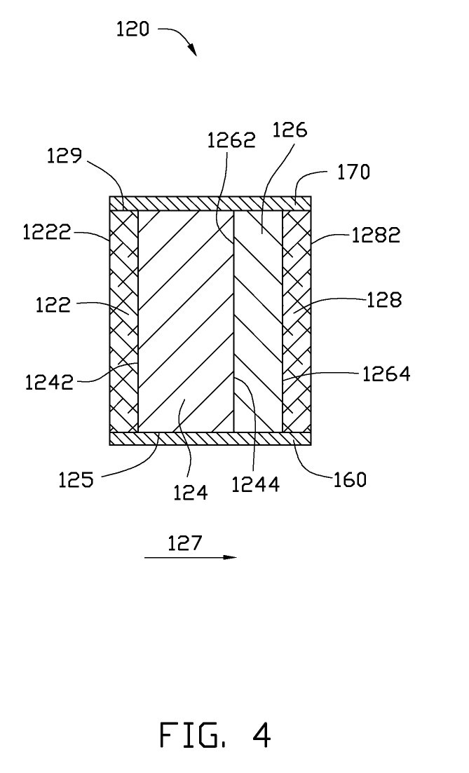

Further, referring to FIGS. 3-4, each of the plurality of solar cells 120 includes a first electrode layer 122, a P-type silicon layer 124, an N-type silicon layer 126, and a second electrode layer 128. The first electrode layer 122, the P-type silicon layer 124, the N-type silicon layer 126, and the second electrode layer 128 of each of the plurality of solar cells 120 can be arranged in series alone a first direction 127, side by side and in contact with each other, in that order. The P-type silicon layer 124 and the N-type silicon layer 126 are in contact with each other and cooperatively form a P-N junction near an interface of the P-type silicon layer 124 and the N-type silicon layer 126. In the embodiment, the first electrode layer 122, the P-type silicon layer 124, the N-type silicon layer 126, and the second electrode layer 128 of each of the plurality of solar cells 120 have the same shape and overlap to each other.

In one embodiment, the shape of each of the plurality of solar cells 120 is a cuboid having a first surface 1222, a second surface 1282, a third surface 121, a fourth surface 123, a fifth surface 125, and a sixth surface 129. A surface of the first electrode layer 122 away from the P-type silicon layer 124 is defined as the first surface 1222. A surface of the second electrode layer 128 away from the N-type silicon layer 126 is defined as the second surface 1282. The first surface 1222 is opposite to the second surface 1282. The third surface 121 is opposite to the fourth surface 123. The fifth surface 125 is opposite to the sixth surface 129. The third surface 121, the fourth surface 123, the fifth surface 125 and the sixth surface 129 are parallel to the first direction 127 and connects the first surface 1222 and the second surface 1282. The sixth surface 129 of each of the plurality of solar cells 120 is used as a photoreceptive surface to directly receive incident light. The sixth surface 129 can be a planar surface or curved surface. The fifth surface 125 is located on a bottom surface of each of the plurality of grooves 112. The thickness of each of the plurality of solar cells 120 is a distance between the fifth surface 125 and the sixth surface 129. The thickness of each of the plurality of solar cells 120 is not limited, and can be set by the light transmittance of the P-type silicon layer 124 and the N-type silicon layer 126. Specifically, if the light transmittance of the P-type silicon layer 124 and the N-type silicon layer 126 is large, the thickness of each of the plurality of solar cells 120 can be appropriately increased to decrease the light transmittance. Consequently, each of the plurality of solar cells 120 can efficiently absorb the light. In one embodiment, the thickness of each of the plurality of solar cells 120 is in a range from about 50 micrometers to about 300 micrometers.

As shown in FIG. 4, the P-type silicon layer 124 has a seventh surface 1242 and an eighth surface 1244 opposite to the seventh surface 1242. The N-type silicon layer 126 has a ninth surface 1262 and an tenth surface 1264 opposite to the ninth surface 1262. The first electrode layer 122 is located on and electrically in contact with the seventh surface 1242. The second electrode layer 128 is located on and electrically in contact with the tenth surface 1264. The eighth surface 1244 and the ninth surface 1262 are in contact with each other and cooperatively form a P-N junction. The P-N junction is near the interface and exposed from the photoreceptive surface, thus the incident light can enter in to the P-N junction directly.

The P-type silicon layer 124 is a laminar structure. The P-type silicon layer 124 has a first top surface (not label) and a first bottom surface (not labeled) connected with the seventh surface 1242 and an eighth surface 1244. An angle between the first top surface and the seventh surface 1242 or the eighth surface 1244 can be larger than 0 degrees and less than 180 degrees. In one embodiment, the angle is about 90 degrees, namely, the first top surface is substantially perpendicular to the seventh surface 1242 and the eighth surface 1244. A material of the P-type silicon layer 124 can be monocrystalline silicon, polycrystalline silicon, or other P-type semiconducting material. A thickness of the P-type silicon layer 124 along the first direction 127 can be in a range from about 200 micrometers to about 300 micrometers. In one embodiment, the P-type silicon layer 124 is a P-type monocrystalline silicon sheet having 200 micrometers in thickness.

The N-type silicon layer 126 is a laminar structure. The N-type silicon layer 126 can be formed by injecting superfluous N-type doping elements (e.g. phosphorus or arsenic) into a silicon sheet. A thickness of the N-type silicon layer 126, along the first direction 127 can be in a range from about 10 nanometers to about 1 micrometer. The N-type silicon layer 126 has a second top surface (not label) and a second bottom surface (not labeled) connected with the ninth surface 1262 and an tenth surface 1264. An angle between the second top surface and the ninth surface 1262 or the tenth surface 1264 can be larger than 0 degrees and less than 180 degrees. In one embodiment, the angle is about 90 degrees and the thickness of the N-type silicon layer 126 is about 50 nanometers.

An inner electric field having a field direction from the N-type silicon layer 126 to the P-type silicon layer 124 is formed, because surplus electrons in the N-type silicon layer 126 diffuse across the P-N junction and reach the P-type silicon layer 124. When a plurality of electron-hole pairs are generated in the P-N junction due to excitation of an incident light, the electrons and the holes are separated from each other under the inner electric field. Specifically, the electrons in the N-type silicon layer 126 move toward the second electrode layer 128, and are gathered by the second electrode layer 128. The holes in the P-type silicon layer 124 move toward the first electrode layer 122, and are gathered by the first electrode layer 122. Thus, a voltage is formed, thereby realizing a conversion from the light energy to the electrical energy.

In use, the incident light does not reach the P-N junction through the first electrode layer 122, namely, the first electrode layer 122 will not obstruct the incident light to reach the P-N junction. Thus, the first electrode layer 122 can be a continuous planar shaped structure coated on the entire seventh surface 1242 of the P-type silicon layer 124, or a lattice shaped structure coated on a part of the seventh surface 1242. A material of the first electrode layer 122 is conductive material, such as metal, silver paste, conducting polymer, indium tin oxide, or carbon nanotube structure. In one embodiment, the first electrode layer 122 is made of a metal material layer having a continuous planar shaped structure and coated on an entirety of the seventh surface 1242. The metal material can be aluminum, copper, or silver. A thickness of the first electrode layer 122 is not limited, and can be in a range from about 50 nanometers to about 300 nanometers. In one embodiment, the first electrode layer 122 is an aluminum sheet having a thickness of 200 nanometers.

Furthermore, the incident light does not reach the P-N junction through the second electrode layer 128. Thus, the second electrode layer 128 can be a continuous planar shaped structure coated on an entirety of the tenth surface 1264 of the N-type silicon layer 126, or a lattice shaped structure partially coated on the tenth surface 1264. A material of the second electrode layer 128 can be conductive material, such as metal, silver paste, conducting polymer, indium tin oxide, or carbon nanotube structure. In one embodiment, the second electrode layer 128 is made of a metal layer having a continuous planar shaped structure and coated on the entirety of the tenth surface 1264. The metal can be aluminum, copper, or silver. A thickness of the second electrode layer 128 is not limited, and can be in a range from about 50 nanometers to about 300 nanometers. In one embodiment, the second electrode layer 128 is an aluminum sheet having a thickness of 200 nanometers.

In addition, the material of the first electrode layer 122 and the second electrode layer 128 can be opaque to avoid leakage of the incident light passing through the first electrode layer 122 and the second electrode layer 128, thus the photoelectric conversion efficiency of each of the plurality of solar cells 120 is improved.

Furthermore, a reflector 150 can be located between each of the plurality of solar cells 120 and each of the plurality of grooves 112 to improve the photoelectric conversion efficiency of each of the plurality of solar cells 120. The reflector 150 can be located on at least one of the third surface 121, the fourth surface 123, and the fifth surface 125. Also, the reflector 150 can be located and fixed on a side wall or a bottom wall of each of the plurality of grooves 112. The reflector 150 is insulated or spaced from the first electrode layer 122 and the second electrode layer 128. The reflector 150 can be a continuous reflection layer made of metal such as aluminum, gold, copper or silver. The thickness of the reflector 150 can be in a range from about 10 nanometers to about 100 micrometers. In one embodiment, the reflector 150 is aluminum foil with a thickness of about 20 micrometers. In one embodiment, the reflector 150 is aluminum foil with a thickness of about 50 nanometers. The reflector 150 can be formed by vacuum evaporation or magnetron sputtering. Also, the reflector 150 can be a plurality of micro-structures formed on the at least one of the third surface 121, the fourth surface 123, and the fifth surface 125. The plurality of micro-structures can be a groove or a protrusion. The plurality of micro-structures can be V-shaped, cylindrical, hemispherical, spherical or pyramid-shaped. The plurality of micro-structures can be formed by etching.

In one embodiment, the reflector 150 is spaced from each of the plurality of solar cells 120 by a transparent insulating layer 160. The transparent insulating layer 160 is located on the covers the entirety of the third surface 121, the fourth surface 123, or the fifth surface 125. The reflector 150 covers an entirety of the transparent insulating layer 160. The transparent insulating layer 160 is made of material with a certain chemical stability, such as diamond-like carbon, silicon, silicon carbide, silicon dioxide, silicon nitride, aluminum oxide or boron nitride. The thickness of the transparent insulating layer 160 can be in a range from about 10 nanometers to about 100 micrometers. In one embodiment, the thickness of the transparent insulating layer 160 can be in a range from about 10 nanometers to about 50 nanometers in order to reduce the light absorption. The transparent insulating layer 160 can be coated by physical vapor deposition or chemical vapor deposition.

Furthermore, an antireflection layer 170 can be located on the sixth surface 129 that is used as the photoreceptive surface to decrease reflection of the incident light and increase absorption of the incident light. The antireflection layer 170 can absorb little light. A material of the antireflection layer 170 can be silicon nitride (Si₃N₄) or silicon dioxide (SiO₂). A thickness of the antireflection layer 170 can be less than 150 nanometers. In one embodiment, the antireflection layer 170 is the silicon nitride layer having the thickness of 900 angstrom (Å).

The incident light irradiates the photoreceptive surface of each of the plurality of solar cells 120. The second electrode layer 128 does not coat the photoreceptive surface, namely, the P-N junction is directly exposed from the photoreceptive surface. Thus, the photons in the incident light directly reach the P-N junction without passing through the second electrode layer 128 and the first electrode layer 122, and can be directly absorbed by the P-N junction. Accordingly, the second electrode layer 128 and the first electrode layer 122 will not prevent the incident light from reaching the P-N junction, thereby increasing the light absorbing efficiency of the P-N junction. Correspondingly, the P-N junction can excite more electron-hole pairs under the irradiation of the incident light. In addition, the second electrode layer 128 can have any shape and cannot obstruct light. In one embodiment, the second electrode layer 128 having a planar shaped structure is coated on the entire of the tenth surface 1264 of the N-type silicon layer 126. Thus, the second electrode layer 128 has a large area, thereby decreasing the diffusing distance of the carriers in the second electrode layer 128 and the interior loss of the carriers, and increasing the photoelectric conversion efficiency of each of the plurality of solar cells 120. Further, the first electrode layer 122 and the second electrode layer 128 will not obstruct the light to irradiate the P-N junction. Thus, the shape and structure of the first electrode layer 122 and the second electrode layer 128 can be arbitrarily set, thereby decreasing the complexity of fabricating each of the plurality of solar cells 120.

The substrate 110 is used to carry, support and connect the plurality of solar cells 120. The substrate 110 is electrically insulate in order to prevent each of the plurality of solar cells 120 from short circuit. The material of the substrate 110 is strong enough to support the plurality of solar cells 120. The material of the substrate 110 can be glass, quartz, silicon, ceramic, rubber, polymer, or wood. When the material of the substrate 110 is conductive, an insulated layer may be formed on a surface of the substrate 110. For example, when the substrate 110 is made of a wafer, a silicon dioxide layer can be formed. In one embodiment, the substrate 110 is made of cellulose triacetate (CTA). The cellulose triacetate is high electrically insulate and transparent.

The plurality of grooves 112 of the substrate 110 are configured to accommodate and fix the plurality of solar cells 120. Each of the plurality of grooves 112 has one of the plurality of solar cells 120 located therein. The shape of each of the plurality of grooves 112 is not limited. The shape of each of the plurality of grooves 112 can be the same as the shape of each of the plurality of solar cells 120 as shown in FIG. 3. In one embodiment, both the shape of each the plurality of solar cells 120 and the shape of each of the plurality of grooves 112 are a cuboid. The size of each of the plurality of grooves 112 matches the size of each of the plurality of solar cells 120. That is, the size of each of the plurality of grooves 112 is equal to or a little greater than the size of each of the plurality of solar cells 120. When the size of each of the plurality of grooves 112 is equal to the size of each of the plurality of solar cells 120, each of the plurality of solar cells 120 can be fixed in each of the plurality of grooves 112 firmly by the friction between each of the plurality of solar cells 120 and each of the plurality of grooves 112. Thus, no binder is needed. When the size of each of the plurality of grooves 112 is a little greater than the size of each of the plurality of solar cells 120, each of the plurality of solar cells 120 can be inserted into and pull out of each of the plurality of grooves 112 easily. Further, the gaps between each of the plurality of solar cells 120 and each of the plurality of grooves 112 can be filled with the binder 140.

Each of the plurality of grooves 112 has a first side wall 1121, a second side wall 1122 opposite to the first side wall 1121, a third side wall 1123, a fourth side wall 1124 opposite to the third side wall 1123, and a bottom surface (not labeled) connecting the first, the second, the third, and the fourth side walls 1121, 1122, 1123, 1124. The thickness of each of the plurality of solar cells 120 can be equal to or greater than the depth of each of the plurality of grooves 112. When the thickness of each of the plurality of solar cells 120 is greater than the depth of each of the plurality of grooves 112, thus, each of the plurality of solar cells 120 can protrude from each of the plurality of grooves 112 so that the photoreceptive surface is exposed to the incident light.

Each of the plurality of solar cells 120 can be fixed on each of the plurality of grooves 112 by the binder 140 or other fixing element (not shown). The binder 140 can be a conductive adhesive such as conductive epoxy, conductive paint, conductive polymer. In one embodiment, the binder 140 is epoxy. Also, in one embodiment, each of the plurality of solar cells 120 can be detachably placed inside of each of the plurality of grooves 112.

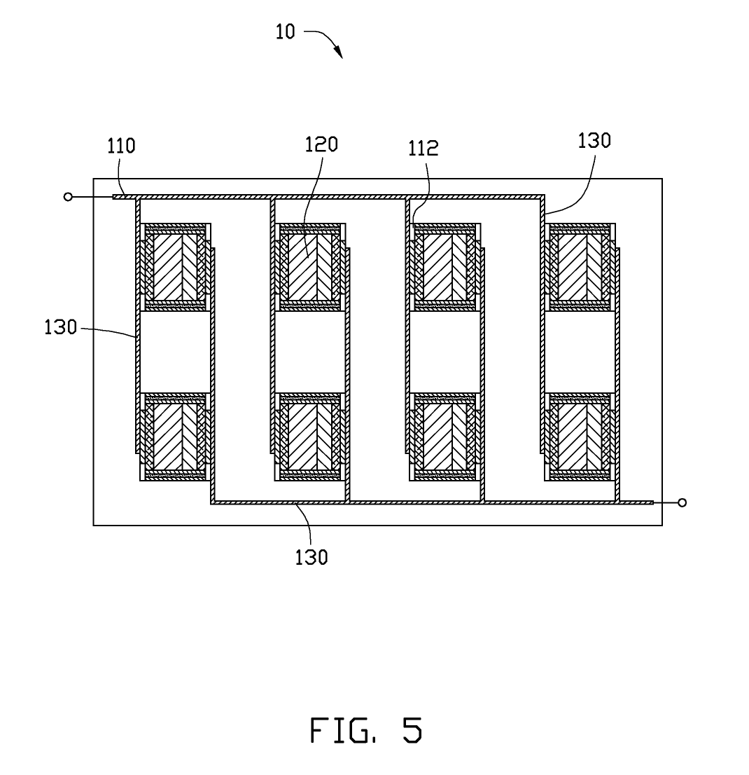

The substrate 110 further includes a plurality of conductive wires 130 between each of the plurality of grooves 112. The plurality of solar cells 120 are electrically connected by the plurality of conductive wires 130. The plurality of conductive wires 130 can be made of metal, conductive polymer, carbon nanotube, or silver paste. In one embodiment, the plurality of conductive wires 130 can be made of epoxy. One end of each of the plurality of conductive wires 130 is electrically connected to the first electrode layer 122 or the second electrode layer 128 of one of the plurality of solar cells 120. Referring to FIG. 1, in one embodiment, one end of each of the plurality of conductive wires 130 is electrically connected to the first electrode layer 122 of one of the plurality of solar cells 120. The other end of each of the plurality of conductive wires 130 is electrically connected to the second electrode layer 128 of adjacent one of the plurality of solar cells 120. Thus, the plurality of solar cells 120 are electrically connected in series. Referring to FIG. 5, in one embodiment, the first electrode layers 122 of the plurality of solar cells 120 are electrically connected by some of the plurality of conductive wires 130 and the second electrode layers 128 of the plurality of solar cells 120 are electrically connected by other of the plurality of conductive wires 130. Thus, the plurality of solar cells 120 are electrically connected in parallel.

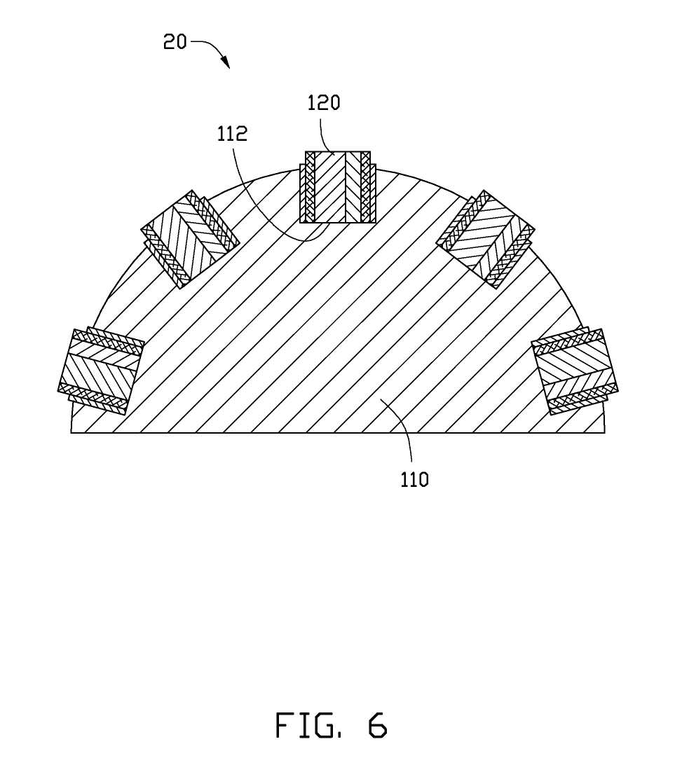

Referring to FIG. 6, a second embodiment of a solar cell system 20 includes a substrate 110 and a plurality of solar cells 120. The substrate 110 defines a plurality of grooves 112 spaced from each other. Each of the plurality of solar cells 120 is located in one of the plurality of grooves 112.

The solar cell system 20 is similar to the solar cell system 10 above except that the plurality of grooves 112 are formed on an arc shaped surface and the plurality of solar cells 120 are arranged along the arc shaped surface. In one embodiment, the substrate 110 is semi-cylindrical and the plurality of solar cells 120 are arranged along the semi-cylindrical surface. In one embodiment, the substrate 110 is hemispherical. Thus, the solar cell system 20 can receive an incident light effectively to improve the photoelectric conversion efficiency.

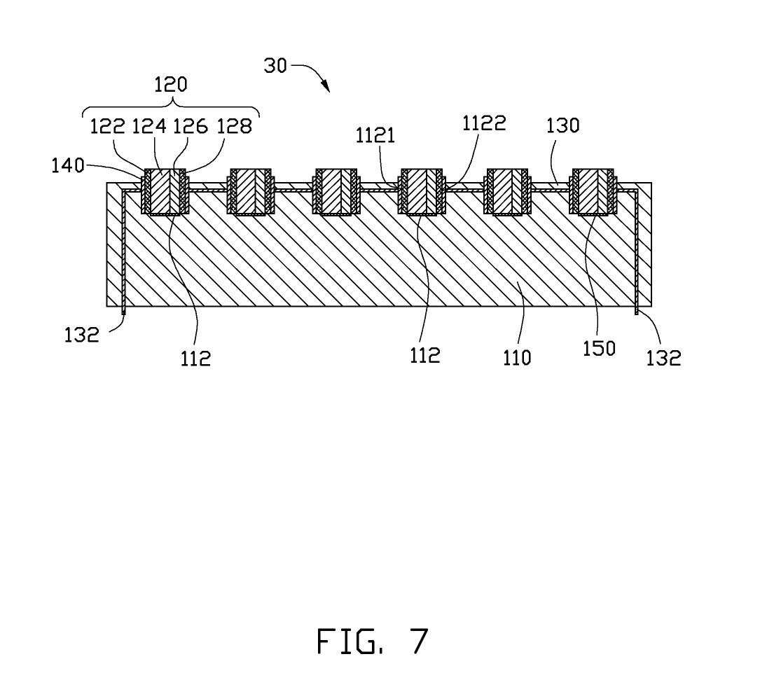

Referring to FIG. 7, a third embodiment of a solar cell system 30 includes a substrate 110 and a plurality of solar cells 120. The substrate 110 defines a plurality of grooves 112 spaced from each other. Each of the plurality of solar cells 120 is located in one of the plurality of grooves 112.

The solar cell system 30 is similar to the solar cell system 10 above except that the plurality of conductive wires 130 are inside in the inner of the substrate 110 and electrically connected to two electrode pads 132. The two electrode pads 132 can be located on bottom surface of the substrate 110. The two electrode pads 132 are used to electrically connect to an external load. Thus, the plurality of conductive wires 130 can be protected and the solar cell system 30 has a long lifespan.

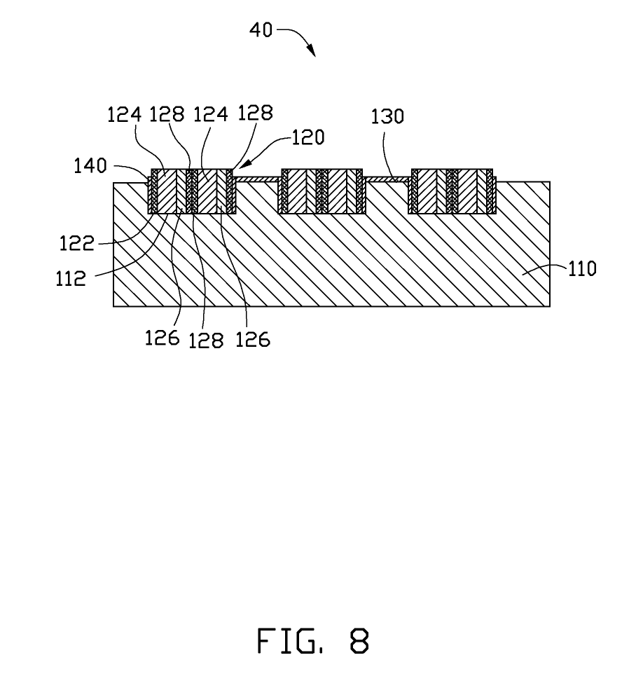

Referring to FIG. 8, a fourth embodiment of a solar cell system 40 includes a substrate 110 and a plurality of solar cells 120. The substrate 110 defines a plurality of grooves 112 spaced from each other. Each of the plurality of solar cells 120 is located in one of the plurality of grooves 112.

The solar cell system 40 is similar to the solar cell system 10 above except that each two of the plurality of solar cells 120 are located in each one of the plurality of grooves 112. The each two of the plurality of solar cells 120 are electrically connected in series by contacting the second electrode layer 128 of one of the each two of the plurality of solar cells 120 to the first electrode layer 122 of the other one of each two of the plurality of solar cells 120.

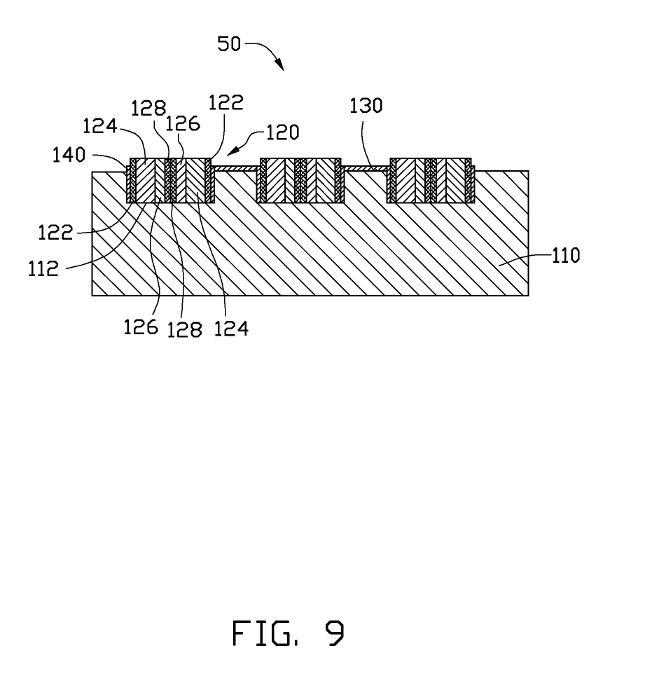

Referring to FIG. 9, a fifth embodiment of a solar cell system 50 includes a substrate 110 and a plurality of solar cells 120. The substrate 110 defines a plurality of grooves 112 spaced from each other. Each of the plurality of solar cells 120 is located in one of the plurality of grooves 112.

The solar cell system 50 is similar to the solar cell system 40 above except that the each two of the plurality of solar cells 120 are electrically connected in parallel by contacting the second electrode layers 128 of the each two of the plurality of solar cells 120 or contacting the first electrode layers 122 of the each two of the plurality of solar cells 120.

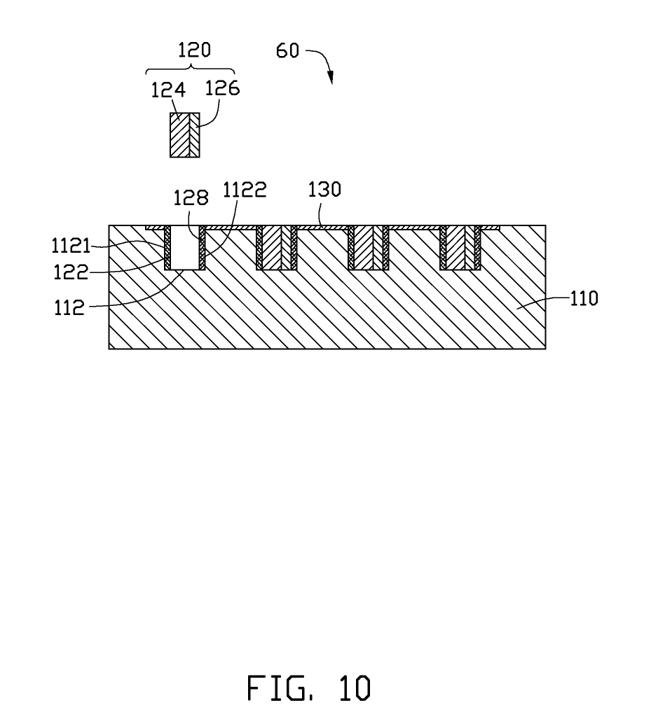

Referring to FIG. 10, a sixth embodiment of a solar cell system 60 includes a substrate 110 and a plurality of solar cells 120. The substrate 110 defines a plurality of grooves 112 spaced from each other. Each of the plurality of grooves 112 has a first side wall 1121, a second side wall 1122 opposite to the first side wall 1121. Each of the plurality of solar cells 120 is located in one of the plurality of grooves 112.

The solar cell system 60 is similar to the solar cell system 10 above except that each of the plurality of solar cells 120 includes only the P-type silicon layer 124 and the N-type silicon layer 126, the first electrode layer 122 is located on and fixed on the first side wall 1121 of each of the plurality of grooves 112, and the second electrode layer 128 is located on and fixed on the second side wall 1122 of each of the plurality of grooves 112. The first electrode layer 122 and the second electrode layer 128 are electrically connected to the plurality of conductive wires 130. The first electrode layer 122 and the second electrode layer 128 can be formed with the plurality of conductive wires 130 together. Each of the plurality of solar cells 120 is detachably placed inside of each of the plurality of grooves 112. Thus, if one of the plurality of solar cells 120 is broken, it is easy to change a new one. Furthermore, a reflector (now shown) can be located on at least one of the third side wall 1123, the fourth side wall 1124 and the bottom surface of each of the plurality of grooves 112. The reflector is insulated from the first electrode layer 122 and the second electrode layer 128. Furthermore, a transparent insulating layer is coated on the reflector. The transparent insulating layer is made of material with a certain chemical stability, such as diamond-like carbon, silicon, silicon carbide, silicon dioxide, silicon nitride, aluminum oxide or boron nitride.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. A solar cell system, comprising:
a substrate comprising a plurality of grooves spaced from each other;
a plurality of solar cells, each of the plurality of solar cells being inside each of the plurality of grooves and comprises:
a first electrode layer, a P-type silicon layer, an N-type silicon layer, and a second electrode layer cooperatively forming an integrated structure, the first electrode layer, the P-type silicon layer, the N-type silicon layer, and the second electrode layer being serially connected with each other along a first direction, a P-N junction near an interface between the P-type silicon layer and the N-type silicon layer, and a photoreceptive surface configured to receive incident light beams directly, the photoreceptive surface being defined by the P-N junction of each of the plurality of solar cells; and
a plurality of reflectors, each of the plurality of reflectors being between each of the plurality of solar cells and the inside of each of the plurality of grooves.

2. The solar cell system of claim 1, wherein the substrate is electrically insulate.

3. The solar cell system of claim 1, wherein the substrate further comprises a plurality of conductive wires, each of the plurality of conducive wires is between each the plurality of grooves, and the plurality of solar cells are electrically connected with each other through the plurality of conductive wires.

4. The solar cell system of claim 3, wherein the plurality of conductive wires are inside of the substrate.

5. The solar cell system of claim 1, wherein the plurality of grooves are formed on an arc shaped surface.

6. The solar cell system of claim 1, wherein a thickness of each of the plurality of solar cells is equal to or greater than a depth of each of the plurality of grooves.

7. The solar cell system of claim 1, wherein the plurality of reflectors is fixed on the plurality of solar cells or fixed on the plurality of grooves.

8. The solar cell system of claim 1, wherein each of the plurality of reflectors is a continuous reflection layer made of metal.

9. The solar cell system of claim 8, further comprising a transparent insulating layer between each of the plurality of reflectors and each of the plurality of solar cells.

10. The solar cell system of claim 1, wherein each of the plurality of reflectors comprises a plurality of micro-structures.

11. The solar cell system of claim 1, wherein each of the plurality of reflectors is insulated from each of the first electrode layer and the second electrode layer.

12. The solar cell system of claim 1, wherein the first electrode layer, the P-type silicon layer, the N-type silicon layer, and the second electrode layer have a same shape and a same size, and are serially connected with each other by overlapping with each other; the integrated structure defines a bottom surface opposite to the photoreceptive surface, and two side surfaces parallel with the first direction.

13. The solar cell system of claim 12, wherein each of the plurality of reflectors is located on at least one of the bottom surface and the two side surfaces of the integrated structure.

14. The solar cell system of claim 1, wherein the photoreceptive surface comprises an antireflection layer coated on the photoreceptive surface, and the antireflection layer has a thickness less than 150 nm.

15. The solar cell system of claim 14, wherein material of the antireflection layer is silicon nitride or silicon dioxide.

16. The solar cell system of claim 1, wherein the photoreceptive surface is a planar surface parallel with the first direction.

17. The solar cell system of claim 1, wherein the photoreceptive surface is a curved surface.

18. The solar cell system of claim 1, wherein each of the plurality of solar cells is attached to the inside of each of the plurality of grooves by a conductive binder.

19. A solar cell system, comprising:
a substrate comprising a plurality of grooves spaced from each other, wherein each of the plurality of grooves has a first side wall having a first electrode layer fixed thereon and a second side wall opposite to the first side wall and having a second electrode layer fixed thereon;
a plurality of solar cells, each of the plurality of solar cells being inside each of the plurality of grooves, each of the plurality of solar cells comprising:
a P-type silicon layer and an N-type silicon layer stacked with each other thereby cooperatively forming an integrated structure, a P-N junction near an interface between the P-type silicon layer and the N-type silicon layer, and a photoreceptive surface configured to receive incident light beams directly, wherein the photoreceptive surface is defined by the P-N junction, the P-type silicon layer is electrically connected to the first electrode layer, and the N-type silicon layer is electrically connected to the second electrode layer; and
a reflector between each of the plurality of solar cells and the inside of each of the plurality of grooves.

20. The solar cell system of claim 19, wherein each of the plurality of solar cells is detachably placed on each of the plurality of grooves.
